(19) United States
(12) Patent Application Publication
(10) Pub. No.: US 2025/0378875 A1
(43) Pub. Date: Dec. 11, 2025

(54) Device and Method for Reading a Memory Cell

(71) Applicant: Taiwan Semiconductor Manufacturing Company, Ltd., Hsinchu (TW)

(72) Inventor: Sanjeev Kumar Jain, Hsinchu (TW)

(21) Appl. No.: 18/739,538

(22) Filed: Jun. 11, 2024

(51) Int. Cl. G11C 11/419

(52) U.S. Cl. CPC G11C 11/419

(57) ABSTRACT

A device includes a sense amplifier and read bit line pre-charger circuit and a local control circuit. The sense amplifier and read bit line pre-charger circuit receives a complement sense amplifier pre-charge signal (SAPRB) and pre-charges the complementary read bit lines in response to the complement sense amplifier pre-charge signal (SAPRB). The local control circuit includes an internal sense amplifier pre-charge signal (SAPRI) generator and a sense amplifier pre-charge signal (SAPR) generator. The internal sense amplifier pre-charge signal (SAPRI) generator receives an internal sense amplifier enable signal (SAEI) and generates an internal sense amplifier pre-charge signal (SAPRI) and an inverted version of the internal sense amplifier pre-charge signal (SAPRI). The sense amplifier pre-charge signal (SAPR) generator receives the inverted version of the internal sense amplifier pre-charge signal (SAPRI) and generates an inverted version of the complement sense amplifier pre-charge signal (SAPR).

### BACKGROUND

A pre-charger of a memory device pre-charges complementary read bit lines of the memory device to a predetermined voltage level in preparation for a read operation on a memory cell of the memory device. During the read operation, a sense amplifier of the memory device amplifies a voltage difference between the complementary read bit lines to determine whether a bit stored in the memory cell is high (1) or low (0).

### BRIEF DESCRIPTION OF THE DRAWINGS

Aspects of the present disclosure are best understood from the following detailed description when read with the accompanying figures:

FIG. 1 is a block diagram illustrating an exemplary device in accordance with various embodiments of the present disclosure;

FIG. 2 is a block/circuit diagram illustrating another exemplary device in accordance with various embodiments of the present disclosure;

FIG. 3 is a timing diagram illustrating the relationships among signals associated with a device in accordance with various embodiments of the present disclosure;

FIG. 4 is a block diagram illustrating an exemplary pre-charge signal generator of a device in accordance with various embodiments of the present disclosure;

FIG. 5 is a circuit diagram illustrating an exemplary internal sense amplifier pre-charge signal (SAPRI) generator of a pre-charge signal generator in accordance with various embodiments of the present disclosure;

FIG. 6 is a circuit diagram illustrating an exemplary read signal (READ) generator of a pre-charge signal generator in accordance with various embodiments of the present disclosure;

FIG. 7 is a circuit diagram illustrating an exemplary sense amplifier pre-charge signal (SAPR) generator of a pre-charge signal generator in accordance with various embodiments of the present disclosure; and

FIG. 8 is a flow chart of an exemplary method of reading a bit stored in a device in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Memory devices, such as a static random access memory (SRAM) device, may be designed to include pre-chargers to assist with certain operations. For example, a pre-charger of a memory device pre-charges complementary read bit lines of the memory device to a predetermined voltage level. This improves the speed at which the memory device is able to determine whether the bit stored in the memory cell is high (1) or low (0) during a read operation of the memory device. Typically, pre-charging in preparation for a next read operation starts after a current read operation ends. This may cause anomalies in the subsequent read operations of the memory device. Such “late” pre-charging may also require a higher supply voltage to provide fast enough pre-charging so as to not affect the next read operation.

Certain systems and methods as described herein can mitigate such read operation anomalies by starting the pre-charging in preparation for a next read operation earlier than or at substantially the same time as a current read operation ends. This permits the design of a memory device to operate at a lower supply voltage, enabling power savings (e.g., up to 12% or more). For example, systems and methods comprise a read signal generator that generates a read signal (READ) associated with a read operation based on an internal sense amplifier pre-charge signal (SAPRI) associated with the pre-charging of complementary read bit lines, in a manner that will be described in detail hereinafter.

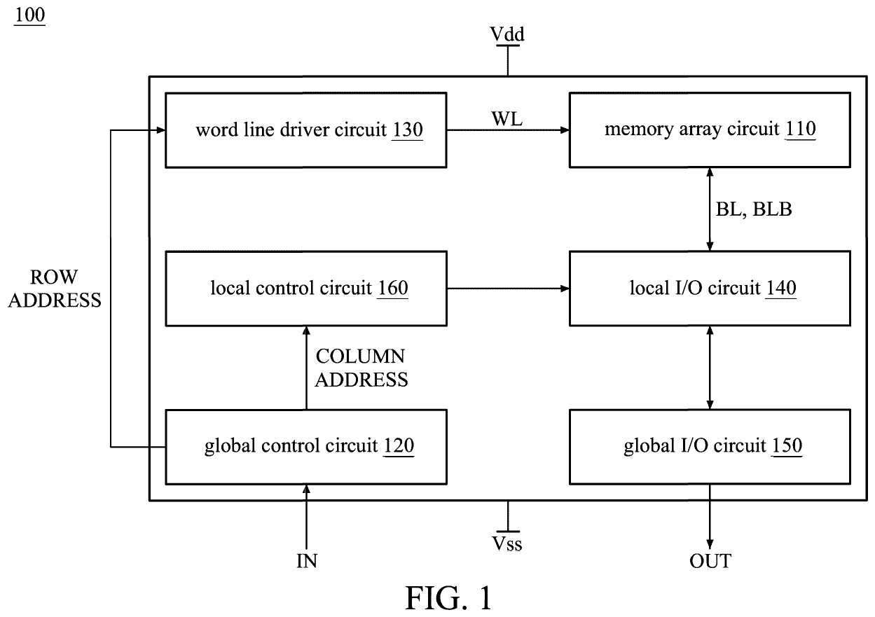

FIG. 1 is a block diagram illustrating an exemplary device 100 in accordance with various embodiments of the present disclosure. As illustrated in FIG. 1, the example device 100, e.g., a memory device, such as an SRAM device, is connected across supply voltages (Vdd, Vss) and includes a memory array circuit 110, a global control circuit 120, a word line driver circuit 130, a local input/output (I/O) circuit 140, a global I/O circuit 150, and a local control circuit 160. The memory array circuit 110 includes a plurality of memory arrays. Each memory array includes a plurality of memory cells arranged in a matrix of rows and columns and each stores a bit, e.g., high (1) or low (0), of data.

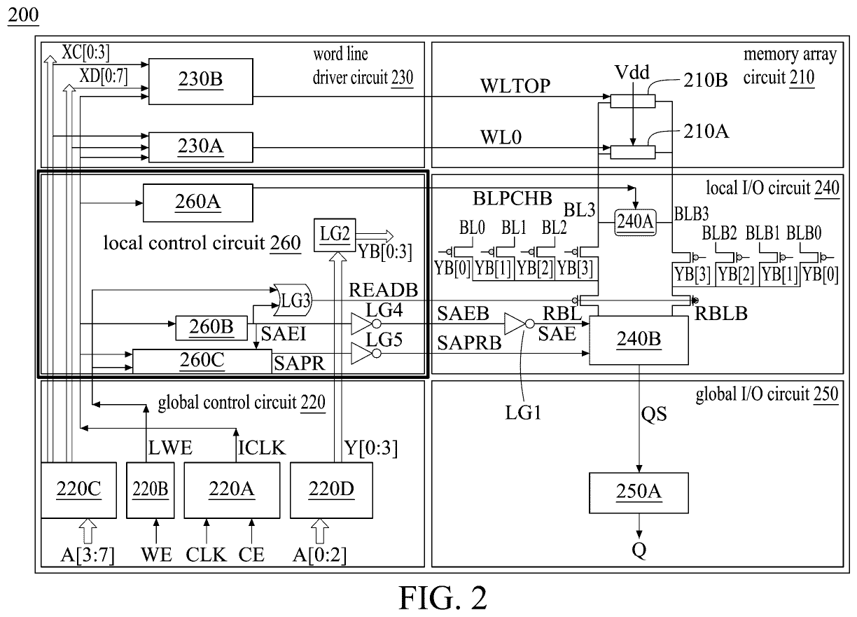

The device 100 further includes a plurality of word lines (WL), each connected to the memory cells in the respective row, and complementary bit lines (BL, BLB) connected to the memory cells in a column. The global control circuit 120 receives an input signal (IN) and generates row and column addresses of a memory cell, e.g., memory cell 210A of FIG. 2, based on the input signal (IN). The word line driver circuit 130 receives the row address and activates one of the word lines (WL), e.g., word line (WL0) of FIG. 2, when a bit is to be read from or written to the memory cell 210A, and deactivates the remaining word lines (WL), e.g., word line (WLTOP) of FIG. 2, to prevent access to, e.g., memory cell 210B of FIG. 2, avoiding unintended alteration of the bit stored in the memory cell 210B.

The local I/O circuit 140 receives the column address and accesses (reads from or writes to), the memory cell 210A. The global I/O circuit 150 transfers a bit read from or to be written to the memory cell 210A between the local I/O circuit 140 and a memory controller external to the device 100. The local control circuit 160 is connected between the global control circuit 120 and the local I/O circuit 140 and controls operation of the local I/O circuit 140 based on the input signal (IN), in a manner that will be described in detail hereinafter.

FIG. 2 is a block/circuit diagram illustrating another exemplary device 200 in accordance with various embodiments of the present disclosure. As illustrated in FIG. 2, the example device 200 is similar to the device 100 and includes a memory array circuit 210, a global control circuit 220, a word line driver circuit 230, a local input/output (I/O) circuit 240, a global I/O circuit 250, and a local control circuit 260. The memory array circuit 210 includes at least one memory array. The memory array includes a plurality of memory cells, e.g., memory cells 210A, 210B, arranged in a matrix of rows and columns and each stores a bit, e.g., high (1) or low (0), of data.

In this exemplary embodiment, the memory cell 210A, 210B is a 6T (six-transistor) memory cell. In an alternative embodiment, the memory cell 210A, 210B may be a 3T memory cell, an 8T transistor, a 1T1C (one transistor, one capacitor) memory cell, a magnetic tunnel junction (MTJ) memory cell, and the like.

The device 200 further includes a plurality of word lines, e.g., word lines (WL0, WLTOP), each connected to the memory cells, e.g., memory cells 210A, 210B, in the respective row. The device 200 further includes complementary bit lines, e.g., complementary bit lines (BL3, BLB3), connected to the memory cells, e.g., memory cells 210A, 210B, in a column. The global control circuit 220 includes an internal clock signal (ICLK) generator 220A, an internal write enable signal (LWE) generator 220B, a row address generator 220C, and a column address generator 220D. The internal clock signal (ICLK) generator 220A receives a chip enable signal (CE) and an external clock signal (CLK) from, e.g., a memory controller external to the device 200, and generates an internal clock signal (ICLK) when the chip enable signal (CE) is asserted, e.g., high (1) or low (0).

The internal write enable signal (LWE) generator 220B receives a write enable signal (WE) from, e.g., the memory controller, and generates an internal write enable signal (LWE) when the write enable signal (WE) is asserted, e.g., high (1). The row address generator 220C receives a first memory cell address (A[3:7]), e.g., from the memory controller, of a memory cell, e.g., memory cell 210A, and generates a row address (XC[0:3], XD[0:7]) of the memory cell 210A. The column address generator 220D receives a second memory cell address (A[0:2]), e.g., from the memory controller, of the memory cell 210A, and generates a column address (Y[0:3]) of the memory cell 210A.

The word line driver circuit 230 includes a plurality of word line drivers 230A, 230B, each receiving the internal clock signal (ICLK) and connected between the row address generator 220C and the respective word line (WL0, WLTOP). The word driver 230A further receives the row address (XC[0:3], XD[0:7]) and activates the word line (WL0) when a bit is to be read from or written to the memory cell 210A. The word line driver 230B further receives the row address (XC[0:3], XD[0:7]) and deactivates the word line (WLTOP) to prevent access to the memory cell 210B, avoiding unintended alteration of the bit stored in the memory cell 210B.

The local I/O circuit 240 includes a bit line (BL) pre-charger 240A, a read bit line (RBL), a complement bit line (RBLB), a plurality of bit line (BL0-BL3) transistors, a plurality of complement bit line (BLB0-BLB3) transistors, a read bit line (RBL) transistor, a complement read bit line (RBLB) transistor, a sense amplifier and read bit line (RBL) pre-charger circuit 240B, and a logic gate (LG1). The bit line (BL) pre-charger 240A is connected between the complementary bit lines (BL3, BLB3), receives a complement bit line pre-charge signal (BLPCHB), and pre-charges the complementary bit lines (BL3, BLB3) to a predetermined voltage level, e.g., halfway between the supply voltages (Vdd, Vss), when the complement pre-charge signal (BLPCHB) is asserted, e.g., high (1) or low (0).

The bit line (BL3) transistor has a first source/drain terminal connected to the bit line (BL3) and a second source/drain terminal connected to a first source/drain terminal of the read bit line (RBL) transistor. The gate terminal of the bit line (BL3) transistor receives a complement column address (YB3). The read bit line (RBL) transistor further has a second source/drain terminal connected to the read bit line (RBL). The gate terminal of the read bit line (RBL) transistor receives a complement read signal (READB).

Similarly, the complement bit line (BLB3) transistor has a first source/drain terminal connected to the complement bit line (BLB3) and a second source/drain terminal connected to a first source/drain terminal of the complement read bit line (RBLB) transistor. The gate terminal of the complement bit line (BLB3) transistor receives a complement column address (YB3). The complement read bit line (RBLB) transistor further has a second source/drain terminal connected to the complement read bit line (RBLB). The gate terminal of the complement read bit line (RBLB) transistor receives a complement read signal (READB).

The sense amplifier and read bit line (RBL) pre-charger circuit 240B is connected between the complementary read bit lines (RBL, RBLB), receives a complement pre-charge signal (SAPRB), and pre-charges the complementary read bit lines (RBL, RBLB) to a predetermined voltage level, e.g., halfway between the supply voltages (Vdd, Vss), when the complement pre-charge signal (SAPRB) is asserted, e.g., low (0). The sense amplifier and read bit line (RBL) pre-charger circuit 240B further receives a sense amplifier enable signal (SAE), amplifies a voltage difference between the complementary read bit lines (RBL, RBLB) to determine whether a bit stored in the memory cell 210A is high (1) or low (0) when the sense amplifier enable signal (SAE) is asserted, e.g., high (1). The sense amplifier and read bit line (RBL) pre-charger circuit 240B further generates a bit (QS) that is high (1) when the voltage level on the read bit line (RBL) is greater than the voltage level on the complement bit line (RBLB). Otherwise, the bit (QS) is low (0).

The logic gate (LG1) is in the form of an inverter, has an input that receives an inverted version of the sense amplifier enable signal (SAE), i.e., a complement sense amplifier enable signal (SAEB), and provides a sense amplifier enable signal (SAE) at an output thereof. The global I/O circuit 250 includes an output latch 250A that receives the bit (QS) and that transmits a bit (Q), which represents the bit stored in the memory cell 210, to the memory controller.

The local control circuit 260 includes a first pre-charge signal generator 260A, a second logic gate (LG2), a third logic gate (LG3), an internal sense amplifier enable signal (SAEI) generator 260B, a fourth logic gate (LG4), a second pre-charge signal generator 260C, and a fifth logic gate (LG5). The first pre-charge signal generator 260A receives an internal clock signal (ICLK) and generates a complement bit line pre-charge (BLPCHB) signal.

The logic gate (LG2) includes one or more inverters, receives a column address (Y[0:3]), and provides an inverted version of the column address (Y[0:3]), i.e., a complement column address (YB[0:3]), at an output thereof. The internal sense amplifier enable signal (SAEI) generator 260B receives the internal clock signal (ICLK) and generates an internal sense amplifier enable signal (SAEI). The logic gate (LG3) is in the form of an OR gate, has a first input that receives the internal write enable signal (LWE) and a second input that receives the internal sense amplifier enable signal (SAEI), and provides a complement read signal (READB) at an output thereof. The logic gate (LG4) is in the form of an inverter, has an input that receives the internal sense amplifier enable signal (SAEI), and provides an inverted version of the internal sense amplifier enable signal (SAEI), i.e., a complement sense amplifier enable signal (SAEB), at an output thereof.

The second pre-charge signal generator 260C receives the internal clock signal (ICLK) and the internal write enable signal (LWE) and generates a sense amplifier pre-charge signal (SAPR). The logic gate (LG5) is in the form of an inverter, has an input that receives the sense amplifier pre-charge signal (SAPR), and provides an inverted version of the sense amplifier pre-charge signal (SAPR), i.e., a complement sense amplifier pre-charge signal (SAPRB), at an output thereof.

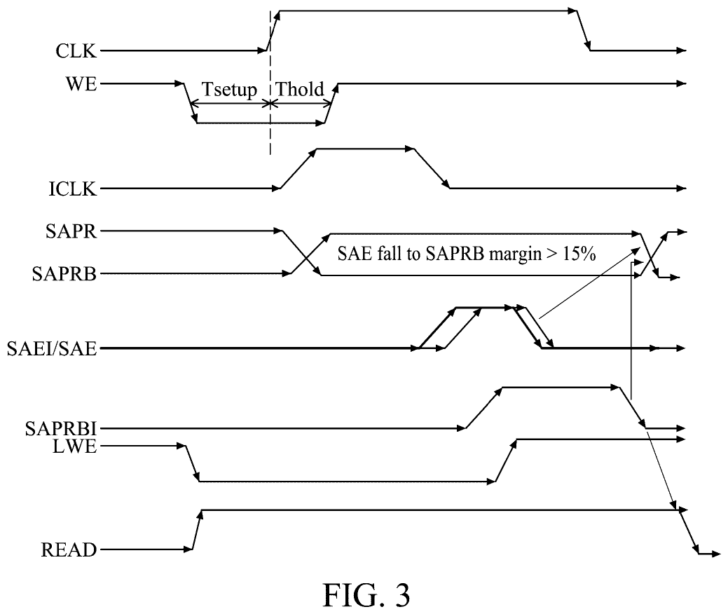

FIG. 3 is a timing diagram illustrating the relationships among signals associated with the device 200 for an exemplary read operation in accordance with various embodiments of the present disclosure. In FIG. 3, when the internal clock signal (ICLK) generator 220A receives an external clock signal (CLK) that is low (0), the internal clock signal (ICLK) generator 220A generates an internal clock signal (ICLK) that is also low (0). In response to the internal clock signal (ICLK), the first pre-charge signal generator 260A generates a complement bit line pre-charge signal (BLPCHB) that is low (0). As a result, the bit line (BL) pre-charger 240A pre-charges the complementary bit lines (BL3, BLB3) to a predetermined voltage level, e.g., halfway between the supply voltages (Vdd, Vss). At this time, in response to the internal clock signal (ICLK), the internal sense amplifier enable signal (SAEI) generator 260B generates an internal sense amplifier enable signal (SAEI) that is low (0) and the logic gate (LG1) generates a sense amplifier enable signal (SAE) that is also low (0). As a result, the sense amplifier and read bit line (RBL) pre-charger circuit 240B is inhibited from amplifying a voltage difference between the complementary read bit lines (RBL, RBLB).

Subsequently, the internal write enable signal (LWE) generator 220B receives a write enable signal (WE) that is high (1) and generates an internal write enable signal (LWE) that is also high (1). In response to the internal write enable signal (LWE) and the internal sense amplifier enable signal (SAEI), the logic gate (LG3) generates a complement read signal (READB) that is high (1), deactivating the read bit line (RBL) and complement read bit line (RBLB) transistors. At this time, in response to the internal clock signal (ICLK), the internal write enable signal (LWE), and the internal sense amplifier enable signal (SAEI), the second pre-charge signal generator 260C generates a sense amplifier pre-charge signal (SAPR) that is high (1) and the logic gate (LG5) generates a complement sense amplifier pre-charge signal (SAPRB) that is low (0). As a result, the sense amplifier and read bit line (RBL) pre-charger circuit 240B pre-charges the complementary read bit lines (RBL, RBLB) to a predetermined voltage level, e.g., halfway between the supply voltages (Vdd, Vss).

Thereafter, the write enable signal (WE) transitions from high (1) to low (0) and the internal write enable signal (LWE) also transitions from high (1) to low (0), commencing a read operation, i.e., as illustrated in FIG. 3, a read signal (READ) transitions from low (0) to high (1). Next, the external clock signal (CLK) transitions from low (0) to high (1) and the internal clock signal (ICLK) also transitions from low (0) to high (1). In response to the internal clock signal (ICLK), the first pre-charge signal generator 260A generates a complement bit line pre-charge signal (BLPCHB) that is high (1). As a result, the bit line (BL) pre-charger 240A is inhibited from pre-charging the bit lines (BL3, BLB3). At this time, the internal sense amplifier enable signal (SAEI) remains low (0) and the sense amplifier enable signal (SAE) also remains low (0). As a result, the sense amplifier and read bit line (RBL) pre-charger circuit 240B is remained inhibited from amplifying a voltage difference between the complementary read bit lines (RBL, RBLB). At the same time, in response to the internal write enable signal (LWE) and the internal sense amplifier enable signal (SAEI), the logic gate (LG3) generates a complement read signal (READB) that is high (1), activating the read bit line (RBL) and complement read bit line (RBLB) transistors. Moreover, in response to the internal clock signal (ICLK), the internal write enable signal (LWE), and the internal sense amplifier enable signal (SAEI), the second pre-charge signal generator 260C generates a sense amplifier pre-charge signal (SAPR) that transitions from high (1) to low (0) and the logic gate (LG5) generates a complement sense amplifier pre-charge signal (SAPRB) that transitions from low (0) to high (1). As a result, the sense amplifier and read bit line (RBL) pre-charger circuit 240B is inhibited from pre-charging the complementary read bit lines (RBL, RBLB).

Subsequently, the row address generator 220C receives a memory cell address (A[3:7]) of the memory cell 210A and generates a row address (XC[0:3], XD[0:7]) of the memory cell 210A. As a result, the word line driver 203A activates the word line (WL0). Similarly, the column address generator 220D receives a memory cell address (A[0:2]) of the memory cell 210A and generates a column address (Y[0:3]) of the memory cell 210A. As a result, the logic gate (LG2) activates the bit line (BL) and complement bit line (BLB) transistors, connecting the complementary bit lines (BL, BLB) to the complementary read bit lines (RBL, RBLB), respectively.

Then, the internal clock signal (ICLK) transitions from high (1) back to low (0). In response to the internal clock signal (ICLK), the internal sense amplifier enable signal (SAEI) generator 260B generates an internal sense amplifier enable signal (SAEI) that transitions from low (0) to high (1) and the logic gate (LG1) generates a sense amplifier enable signal (SAE) that also transitions from low (1) to high (1). As a result, the sense amplifier and read bit line (RBL) pre-charger circuit 240B amplifies a voltage difference between the complementary read bit lines (RBL, RBLB) and generates a bit (QS) that is high (1) when the voltage level on the read bit line (RBL) is greater than the voltage level on the complement read bit line (RBLB). Otherwise, the bit (QS) is low (0).

Subsequently, the internal clock signal (ICLK) remains low (0), the internal write enable signal (LWE) transitions from low (0) back to high (1), and the sense amplifier enable signal (SAE) transitions from high (1) back to low (0). In response to the internal clock signal (ICLK) and the internal write enable signal (LWE), the second pre-charge signal generator 260C generates a sense amplifier pre-charge signal (SAPR) that transitions from low (0) back to high (1) and the logic gate (LG5) generates a complement sense amplifier pre-charge signal (SAPRB) that transitions from high (1) back to low (0). As a result, the sense amplifier and read bit line (RBL) pre-charger circuit 240B pre-charges the complementary read bit lines (RBL, RBLB), in preparation for the next read operation. Thereafter, the current read operation ends, i.e., as illustrated in FIG. 3, the read signal (READ) transitions from high (1) back to low (0).

In this exemplary embodiment, as illustrated in FIG. 3, the falling edge of the complement sense amplifier pre-charge signal (SAPRB) occurs earlier than the falling edge of the read signal (READ). In an alternative embodiment, the falling edge of the complement sense amplifier pre-charge signal (SAPRB) occurs at substantially the same time as the falling edge of the read signal (READ).

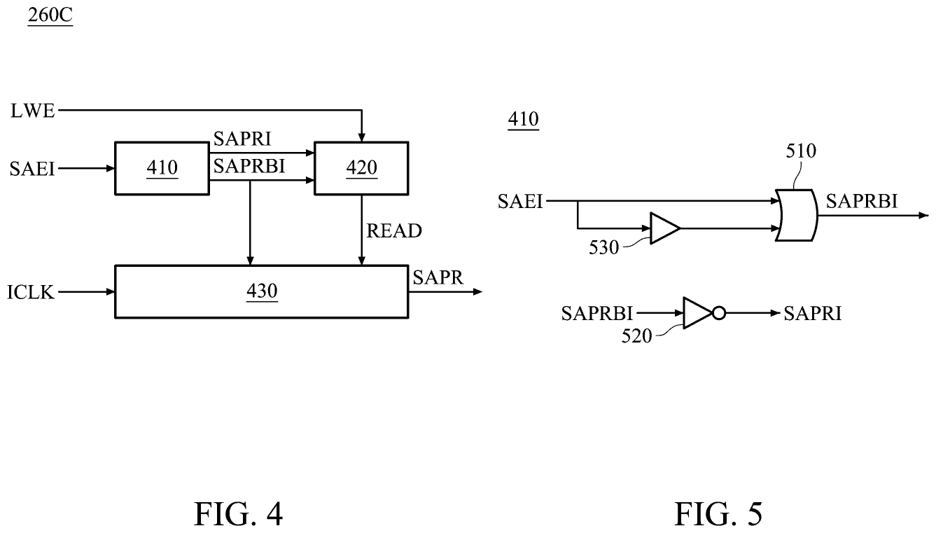

FIG. 4 is a block diagram illustrating an exemplary pre-charge signal generator 260C of the device 100 in accordance with various embodiments of the present disclosure. As illustrated in FIG. 4, the example pre-charge signal generator 260C includes an internal sense amplifier pre-charge signal (SAPRI) generator 410, a read signal (READ) generator 420, and a sense amplifier pre-charge signal (SAPR) generator 430. The internal sense amplifier pre-charge signal (SAPRI) generator 410 receives an internal sense amplifier enable signal (SAEI) and generates an internal sense amplifier pre-charge signal (SAPRI) and an inverted version of the internal sense amplifier pre-charge signal (SAPRI), i.e., a complement internal sense amplifier pre-charge signal (SAPRBI).

The read signal (READ) generator 420 receives an internal write enable signal (LWE), the internal sense amplifier pre-charge signal (SAPRI), and a complement internal sense amplifier pre-charge signal (SAPRBI) and generates a read signal (READ). The sense amplifier pre-charge signal (SAPR) generator 430 receives an internal clock signal (ICLK), the complement internal sense amplifier pre-charge signal (SAPRBI), and the read signal (READ) and generates a sense amplifier pre-charge signal (SAPR).

In an exemplary read operation, with further reference to FIG. 3, when the internal clock signal (ICLK) is low (0), the internal write enable signal (LWE) is high (1), and the internal sense amplifier enable signal (SAEI) is low (0), the internal sense amplifier pre-charge signal (SAPRI) generator 410 generates an internal sense amplifier pre-charge signal (SAPRI) that is high (1) and a complement internal sense amplifier pre-charge signal (SAPRBI) that is low (0), the read signal (READ) generator 420 generates a read signal (READ) that is low (0), and the sense amplifier pre-charge signal (SAPR) generator 430 generates a sense amplifier pre-charge signal (SAPR) that is high (1). At this time, the sense amplifier and read bit line (RBL) pre-charger circuit 240B is pre-charging the complementary bit lines (RBL, RBLB) to a predetermined voltage level.

Subsequently, when the internal clock signal (ICLK) transitions from low (0) to high (1), the internal write enable signal (LWE) transitions from high (1) to low (0), and the internal sense amplifier enable signal (SAEI) remains low (0), the internal sense amplifier pre-charge signal (SAPRI) generator 410 generates an internal sense amplifier pre-charge signal (SAPRI) that remains high (1) and a complement internal sense amplifier pre-charge signal (SAPRBI) that remains low (0), the read signal (READ) generator 420 generates a read signal (READ) that is high (1), and the sense amplifier pre-charge signal (SAPR) generator 430 generates a sense amplifier pre-charge signal (SAPR) that transitions from high (1) to low (0). At this time, the sense amplifier and read bit line (RBL) pre-charger circuit 240B is inhibited from pre-charging the complementary bit lines (RBL, RBLB).

Thereafter, when the internal clock signal (ICLK) transitions from high (1) back to low (0), the internal write enable signal (LWE) remains low (0), and the internal sense amplifier enable signal (SAEI) transitions from low (0) to high (1), the internal sense amplifier pre-charge signal (SAPRI) generator 410 generates an internal sense amplifier pre-charge signal (SAPRI) that that is low (0) and a complement internal sense amplifier pre-charge signal (SAPRBI) that transitions from low to high (1), the read signal (READ) generator 420 generates a read signal (READ) that remains high (1), and the sense amplifier pre-charge signal (SAPR) generator 430 generates a sense amplifier pre-charge signal (SAPR) that remains low (0). At this time, the sense amplifier and read bit line (RBL) pre-charger circuit 240B is amplifying a voltage difference between complementary bit lines (RBL, RBLB).

Subsequently, when the internal clock signal (ICLK) remains low (0), the internal write enable signal (LWE) remains high (1), and the internal sense amplifier enable signal (SAEI) transitions from high (1) back to low (0), the internal sense amplifier pre-charge signal (SAPRI) generator 410 generates an internal sense amplifier pre-charge signal (SAPRI) that transitions from low (0) back to high (1) and a complement internal sense amplifier pre-charge signal (SAPRBI) that transitions from high (1) back to low (0), the read signal (READ) generator 420 generates a read signal (READ) that transitions from high (1) to back low (0) and the sense amplifier pre-charge signal (SAPR) generator 430 generates a sense amplifier pre-charge signal (SAPR) that transitions from high (1) back to low (0). At this time, the sense amplifier and read bit line (RBL) pre-charger circuit 240B is pre-charging the complementary bit lines (RBL, RBLB), in preparation for the next read operation.

Example supporting circuitry for an internal sense amplifier pre-charge signal (SAPRI) generator 410 of the pre-charge signal generator 260C is depicted in FIG. 5. It is understood that this circuitry is provided by way of example, not by limitation, and other suitable internal sense amplifier pre-charge signal (SAPRI) generator 410 circuitry are within the scope of the present disclosure. FIG. 5 is a circuit diagram illustrating an exemplary internal sense amplifier pre-charge signal (SAPRI) generator 410 of the pre-charge signal generator 260C in accordance with various embodiments of the present disclosure. As illustrated in FIG. 5, the internal sense amplifier pre-charge signal (SAPRI) generator 410 includes logic gates 510, 520.

The logic gate 510 is in the form of an OR gate, has a first input that receives the internal sense amplifier enable signal (SAEI) and a second input that receives a delayed version of the internal sense amplifier enable signal (SAEI), and generates a complement internal sense amplifier pre-charge signal (SAPRBI) in response to the internal sense amplifier enable signal (SAEI) and the delayed version of the internal sense amplifier enable signal (SAEI). For example, the internal sense amplifier pre-charge signal (SAPRI) generator 410 further includes a delay element 530 connected between the first and second inputs of the sixth logic gate 510. The delay element 530 receives and introduces a delay to the internal sense amplifier enable signal (SAEI) and generates the delayed version of the internal sense amplifier enable signal (SAEI). In certain embodiments, the delay element 530 includes a buffer circuit, a resistive-capacitive (RC) delay circuit, or a buffer circuit and an RC delay circuit.

The logic gate inverter 520 is in the form of an inverter, has an input that is connected to an output of the logic gate 510 and that receives the complement internal sense amplifier pre-charge signal (SAPRBI), and generates an inverted version of the complement internal sense amplifier pre-charge signal (SAPRBI), i.e., an internal sense amplifier pre-charge signal (SAPRI).

In an exemplary read operation, with further reference to FIG. 3, when the internal sense amplifier enable signal (SAEI) is low (0), the complement internal sense amplifier pre-charge signal (SAPRBI) is also low (0) and the internal sense amplifier pre-charge signal (SAPRI) is high (1). At this time, the sense amplifier and read bit line (RBL) pre-charger circuit 240B is pre-charging the complementary bit lines (RBL, RBLB) to a predetermined voltage level.

Subsequently, when the internal sense amplifier enable signal (SAEI) transitions from low (0) to high (1), the complement internal sense amplifier pre-charge signal (SAPRBI) transitions from low (0) to high (1) and the internal sense amplifier pre-charge signal (SAPRI) transitions from high (1) to low (0). At this time, the sense amplifier and read bit line (RBL) pre-charger circuit 240B is amplifying a voltage difference between the complementary read bit lines (RBL, RBLB).

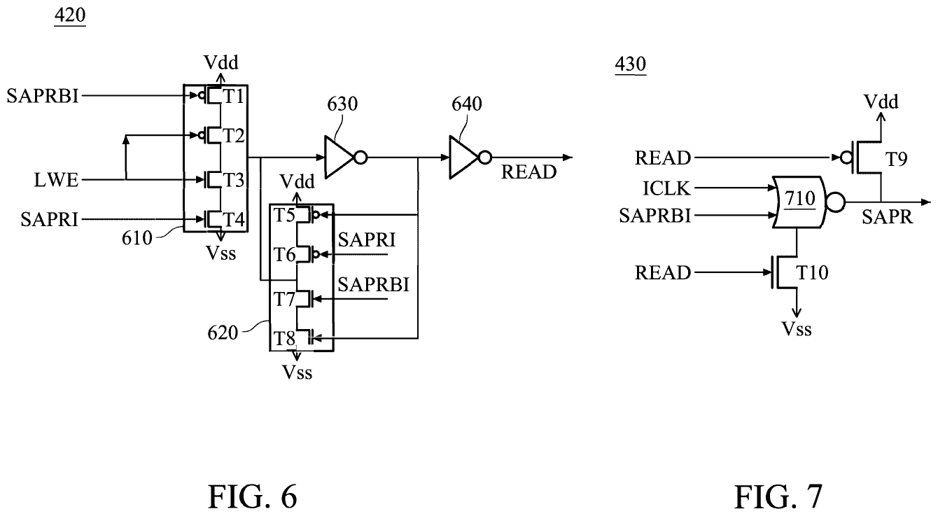

Example supporting circuitry for read signal (READ) generator 420 of the second pre-charge signal generator 260C is depicted in FIG. 6. It is understood that this circuitry is provided by way of example, not by limitation, and other suitable read signal (READ) generator 420 circuitry are within the scope of the present disclosure. FIG. 6 is a circuit diagram illustrating an exemplary read signal (READ) generator 420 of the second pre-charge signal generator 260C in accordance with various embodiments of the present disclosure. As illustrated in FIG. 6, the read signal (READ) generator 420 includes a first transistor module 610, a second transistor module 620, and logic gates 630, 640. The first transistor module 610 includes a pair of p-type metal-oxide-semiconductor (PMOS) transistors (T1, T2) and a pair of n-type metal-oxide-semiconductor (NMOS) transistors (T3, T4). The PMOS transistor (T1) has a first source/drain terminal that receives the supply voltage (Vdd). The PMOS transistor (T2) has a first source/drain terminal connected to a second source/drain terminal of the PMOS transistor (T1). The NMOS transistor (T3) has a first source/drain terminal connected to a second source/drain terminal of the PMOS transistor (T4). The NMOS transistor (T4) has a first source/drain terminal connected to a second source/drain terminal of the NMOS transistor (T3) and a second source/drain terminal connected to the supply voltage (Vss).

In addition, the PMOS transistor (T1) has a gate terminal that receives a complement internal sense amplifier pre-charge signal (SAPRBI). The NMOS transistor (T3) has a gate terminal that is connected to a gate terminal of the PMOS transistor (T2) and that receives an internal write enable signal (LWE). The NMOS transistor (T4) has a gate terminal that receives an internal sense amplifier pre-charge signal (SAPRI).

Similarly, the second transistor module 620 includes a pair of PMOS transistors (T5, T6) and NMOS transistors (T7, T8). The PMOS transistor (T5) has a first source/drain terminal that receives the supply voltage (Vdd). The PMOS transistor (T6) has a first source/drain terminal connected to a second source/drain terminal of the PMOS transistor (T5). The NMOS transistor (T7) has a first source/drain terminal connected to a second source/drain terminal of the PMOS transistor (T6). The NMOS transistor (T8) has a first source/drain terminal connected to a second source/drain terminal of the NMOS transistor (T7) and a second source/drain terminal connected to the supply voltage (Vss).

In addition, the PMOS transistor (T6) has a gate terminal that receives the internal sense amplifier pre-charge signal (SAPRI). The NMOS transistor (T7) has a gate terminal that receives the complement internal sense amplifier pre-charge signal (SAPRBI).

The logic gate 630 is in the form of an inverter, has an input connected to the second source/drain terminal of the PMOS transistor (T2), the first source/drain terminal of the NMOS transistor (T3), the second source/drain terminal of the PMOS transistor (T6), and the first source/drain terminal of the NMOS transistor (T7).

The logic gate 640 is in the form of an inverter and has an input connected to an output of the eighth logic gate 630, a gate terminal of the PMOS transistor (T5), and a gate terminal of the NMOS transistor (T8), and provides a read signal (READ) at an output thereof.

In an exemplary read operation, with further reference to FIG. 3, when the internal write enable signal (LWE) is low (0), the internal sense amplifier pre-charge signal (SAPRI) is high (1), and the complement internal sense amplifier pre-charge signal (SAPRBI) is low (0), the PMOS transistors (T1, T2) are turned on. This connects the input of the logic gate 630 to the supply voltage (Vdd). As a result, the read signal (READ) is high (1). At this time, the sense amplifier and read bit line (RBL) pre-charger circuit 240B is pre-charging the complementary bit lines (RBL, RBLB) to a predetermined voltage level.

Subsequently, when the internal write enable signal (LWE) transitions from low (0) to high (1), the complement internal sense amplifier pre-charge signal (SAPRBI) transitions from low (0) to high (1), and the internal sense amplifier pre-charge signal (SAPRI) transitions from high (1) to low (0), and the PMOS transistors (T5, T6) are turned on. This connects the input of the logic gate 630 to the supply voltage (Vdd). As a result, the read signal (READ) remains high (1). This indicates that the sense amplifier and read bit line (RBL) pre-charger circuit 240B is amplifying a voltage difference between complementary bit lines (RBL, RBLB).

Thereafter, when the internal write enable signal (LWE) is high (1), the complement internal sense amplifier pre-charge signal (SAPRBI) transitions from high (1) back to low (0), and the internal sense amplifier pre-charge signal (SAPRI) transitions from high (1) to low (0), the PMOS transistors (T3, T4) are turned on. This connects the input of the logic gate 630 to the supply voltage (Vss). As a result, the read signal (READ) transitions from high (1) to low (0). At this time, the sense amplifier and read bit line (RBL) pre-charger circuit 240B is pre-charging the complementary bit lines (RBL, RBLB), in preparation for the next read operation.

Example supporting circuitry for a sense amplifier pre-charge signal (SAPR) generator 430 of the pre-charge signal generator 260C is depicted in FIG. 7. It is understood that this circuitry is provided by way of example, not by limitation, and other suitable sense amplifier pre-charge signal (SAPR) generator 430 circuitry are within the scope of the present disclosure. FIG. 7 is a circuit diagram illustrating an exemplary sense amplifier pre-charge signal (SAPR) generator 430 of the pre-charge signal generator 260C in accordance with various embodiments of the present disclosure. As illustrated in FIG. 7, the sense amplifier pre-charge signal (SAPR) generator 430 includes a logic gate 710, a PMOS transistor (T9), and an NMOS transistor (T10). The logic gate 710 is in the form of a NOR gate, has a first input that receives an internal clock signal (ICLK) and a second input that receives a complement internal sense amplifier pre-charge signal (SAPRBI), and provides a sense amplifier pre-charge signal (SAPR) at an output thereof.

The PMOS transistor (T9) has a first source/drain terminal that receives the supply voltage (Vdd), a second source/drain terminal connected to the output of the logic gate 710, and a gate terminal that receives a read signal (READ). The NMOS transistor (T10) has a first source/drain terminal connected to supply node of the logic gate 710, a second source/drain terminal that receives the supply voltage (Vss), and a gate terminal that receives the read signal (READ).

In an exemplary read operation, when the internal clock signal (ICLK) is low (0), the complement internal sense amplifier pre-charge signal (SAPRBI) is low (0), and the read signal (READ) is low (0), the PMOS transistor (T9) is turned on. This connects the output of the logic gate 710 the supply voltage (Vdd). As a result, the output the sense amplifier pre-charge signal (SAPR) is high (1). At this time, the sense amplifier and read bit line (RBL) pre-charger circuit 240B is pre-charging the complementary read bit lines (RBL, RBLB) to a predetermined voltage level.

Subsequently, when the internal clock signal (ICLK) is low (0), the complement internal sense amplifier pre-charge signal (SAPRBI) is high (0), and the read signal (READ) is high (1), the sense amplifier pre-charge signal (SAPR) is low (0). At this time, the sense amplifier and read bit line (RBL) pre-charger circuit 240B is amplifying a voltage difference between complementary bit lines (RBL, RBLB).

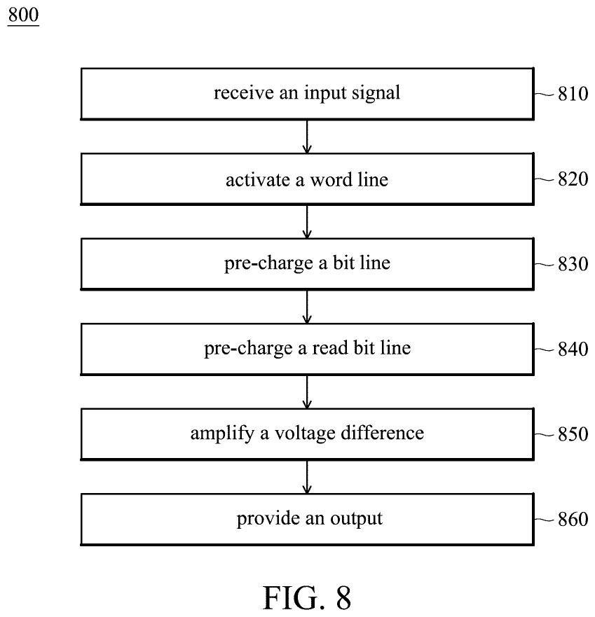

FIG. 8 is a flow chart of an exemplary method 800 of reading a bit stored in a memory cell of the device 100 in accordance with various embodiments of the present disclosure. The example method 800 will now be described with further reference to FIGS. 2-7 for ease of understanding. It is understood that the method 800 is applicable to structures other than those of FIGS. 2-7. Further, it is understood that additional operations can be provided before, during, and after the method 800, and some of the operations described below can be replaced or eliminated, in an alternative embodiment of the method 800.

In operation 810, the global control circuit 120 receives an input signal (IN). In an exemplary embodiment, operation 810 includes: the internal clock signal (ICLK) generator 220A receiving an external clock signal (CLK) and generating an internal clock signal (ICLK); the internal write enable signal (LWE) generator 220B receiving a write enable signal (WE) and generating an internal write enable signal (LWE); the row address generator 220C receiving an address (A[0:7]) and generating row address (XC[0:3], XD[0:7]) of a memory cell, e.g., memory cell 210A; and the column address generator 220D receiving a memory address (A[0:2]) and generating a column address (Y[0:3]) of the memory cell 210A.

In operation 820, the word line driver 230 receives the internal clock signal (ICLK) and the row address (XC[0:3], XD[0:7]) and activates the word line (WL0). In operation 830, the bit line (BL) pre-charger 240A a complement bit line pre-charge signal (BLPCHB) and pre-charges the bit line (BL3) and the complement bit line (BLB3) to a predetermined voltage level, e.g., halfway between the supply voltages (Vdd, Vss). In an exemplary embodiment, operation 830 includes: the pre-charge signal generator 260A receiving the internal clock signal (ICLK) and generating the complement bit line pre-charge signal (BLPCHB); and the logic gate (LG2) receiving the column address (YB[0:3]) and activating the bit line (BL3) transistor and the complement bit line (BLB3) transistor.

In operation 840, the sense amplifier and read bit line (RBL) pre-charger circuit 240B receives a complement sense amplifier pre-charge signal (SAPRB) and pre-charges the complementary read bit lines (RBL, RBLB) to a predetermined voltage level, e.g., halfway between the supply voltages (Vdd, Vss). In an exemplary embodiment, operation 840 includes: the internal sense amplifier enable signal (SAEI) generator 260B receiving the internal clock generator (ICLK) and generating an internal sense amplifier enable signal (SAEI); the internal sense amplifier pre-charge signal (SAPRI) generator 410 receiving the internal sense amplifier enable signal (SAEI) and generating an internal sense amplifier pre-charge signal (SAPRI) and a complement internal sense amplifier pre-charge signal (SAPRBI); the read signal (READ) generator 420 receiving an internal write enable signal (LWE), the internal sense amplifier pre-charge signal (SAPRI), and the complement internal sense amplifier pre-charge signal (SAPRBI), and generating a read signal (READ); the sense amplifier pre-charge signal (SAPR) generator 430 receiving the internal clock signal (ICLK), the complement internal sense amplifier pre-charge signal (SAPRBI), and the read signal (READ) and generating a sense amplifier pre-charge signal (SAPR); the logic gate (LG5) receiving the sense amplifier pre-charge signal (SAPR) and generating an inverted version of the sense amplifier pre-charge signal (SAPR), i.e., the complement sense amplifier pre-charge signal (SAPRB); and the logic gate (LG3) receiving the internal write enable signal (LWE) and the internal sense amplifier enable signal (SAEI) and activating the read bit line (RBL) transistor and the complement read bit line (RBLB) transistor.

In operation 850, the sense amplifier and read bit line (RBL) pre-charger circuit 240B receives a sense amplifier enable signal (SAE), amplifies a voltage difference between the read bit line (RBL) and the complement read bit line (RBLB), and generates a bit (QS) that is high (1) when a voltage level on the read bit line (RBL) is greater than a voltage level on the complement read bit line (RBLB). Otherwise, the bit (QS) is low (0). In an exemplary embodiment, operation 850 includes: the logic gate (LG4) receiving the internal sense amplifier enable signal (SAEI) and generating an inverted version of the internal sense amplifier enable signal (SAEI), i.e., a complement sense amplifier enable signal (SAEB); the logic gate (LG1) receiving the complement sense amplifier enable signal (SAEB) and generating an inverted version of the sense amplifier enable signal (SAEB), i.e., the sense amplifier enable signal (SAE). In operation 860, the output latch 250 receives the bit (QS) at an input thereof and provides an bit (Q) at an output thereof that corresponds to the bit (QS).

In an embodiment, a device comprises a memory array circuit, a global I/O circuit, a local I/O circuit, and a local control circuit. The memory array circuit stores data therein. The global I/O circuit receives or transmits the data. The local I/O circuit transfers the data between the memory array circuit and the global I/O circuit and includes complementary read bit lines and a sense amplifier and read bit line pre-charger circuit. The sense amplifier and read bit line pre-charger circuit is connected between the complementary read bit lines and receives a complement sense amplifier pre-charge signal (SAPRB) and pre-charges the complementary read bit lines in response to the complement sense amplifier pre-charge signal (SAPRB). The local control circuit includes an internal sense amplifier pre-charge signal (SAPRI) generator and a sense amplifier pre-charge signal (SAPR) generator. The internal sense amplifier pre-charge signal (SAPRI) generator receives an internal sense amplifier enable signal (SAEI) and generates an internal sense amplifier pre-charge signal (SAPRI) and an inverted version of the internal sense amplifier pre-charge signal (SAPRI). The sense amplifier pre-charge signal (SAPR) generator receives the inverted version of the internal sense amplifier pre-charge signal (SAPRI) and generates an inverted version of the complement sense amplifier pre-charge signal (SAPR).

In another embodiment, a device comprises a memory array circuit, a global I/O circuit, a local I/O circuit, and a local control circuit. The memory array circuit stores data therein. The global I/O receives or transmits the data. The local I/O circuit transfers the data between the memory array circuit and the global I/O circuit and includes complementary read bit lines and a sense amplifier and read bit line pre-charger circuit. The sense amplifier and read bit line pre-charger circuit is connected between the complementary read bit lines and receives a complement sense amplifier pre-charge signal (SAPRB) and pre-charges the complementary read bit lines in response to the complement sense amplifier pre-charge signal (SAPRB). The local control circuit includes a complement internal sense amplifier pre-charge signal (SAPRBI) generator and a sense amplifier pre-charge signal (SAPR) generator. The complement internal sense amplifier pre-charge signal (SAPRBI) generator receives an internal sense amplifier enable signal (SAEI) and a delayed version of the internal sense amplifier enable signal (SAEI) and generates a complement internal sense amplifier pre-charge signal (SAPRBI). The sense amplifier pre-charge signal (SAPR) generator receives the complement internal sense amplifier pre-charge signal (SAPRBI) and generates a sense amplifier pre-charge signal (SAPR).

In another embodiment, a method for reading a memory cell comprises: generating an internal sense amplifier enable signal (SAEI); generating an internal sense amplifier pre-charge signal (SAPRI) and an inverted version of the internal sense amplifier pre-charge signal (SAPRI) in response to the internal sense amplifier enable signal (SAEI); receiving the inverted version of the internal sense amplifier pre-charge signal (SAPRI); generating an inverted version of a complement sense amplifier pre-charge signal (SAPRB) in response to the inverted version of the internal sense amplifier pre-charge signal (SAPRI); pre-charging complementary read bit lines of the device; amplifying a voltage difference between the complementary read bit lines; and providing an output that corresponds to a voltage level on one of the complementary read bit lines.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device comprising:
a memory array circuit configured to store data therein;
a global input/output (I/O) circuit configured to receive or transmit the data;
a local I/O circuit configured to transfer the data between the memory array circuit and the global I/O circuit and including:
complementary read bit lines; and
a sense amplifier and read bit line pre-charger circuit connected between the complementary read bit lines and configured to receive a complement sense amplifier pre-charge signal (SAPRB) and to pre-charge the complementary read bit lines in response to the complement sense amplifier pre-charge signal (SAPRB); and
a local control circuit including:
an internal sense amplifier pre-charge signal (SAPRI) generator configured to receive an internal sense amplifier enable signal (SAEI) and to generate an internal sense amplifier pre-charge signal (SAPRI) and an inverted version of the internal sense amplifier pre-charge signal (SAPRI); and
a sense amplifier pre-charge signal (SAPR) generator configured to receive the inverted version of the internal sense amplifier pre-charge signal (SAPRI) and to generate an inverted version of the complement sense amplifier pre-charge signal (SAPR).

2. The device of claim 1, wherein:
the local control circuit further includes a read signal (READ) generator configured to receive the internal sense amplifier pre-charge signal (SAPRI) and the inverted version of the internal sense amplifier pre-charge signal (SAPRI) and to generate a read signal (READ); and
the sense amplifier pre-charge signal (SAPR) generator is configured generate the inverted version of the sense amplifier pre-charge signal (SAPR) in response further to the read signal (READ).

3. The device of claim 1, wherein the sense amplifier and read bit line pre-charger circuit is further configured to receive a sense amplifier enable signal (SAE) and to amplify a voltage difference between the complementary read bit lines in response to the sense amplifier enable signal (SAE).

4. The device of claim 3, wherein the local control circuit is configured to receive an internal clock signal (ICLK) and to generate an inverted version of the sense amplifier enable signal (SAE).

5. The device of claim 1, wherein:
the local I/O circuit further includes complementary bit lines, wherein memory cells of the memory array circuit is connected between the complementary bit lines; and
the local I/O circuit is further configured to receive a complement bit line pre-charge signal (BLPCHB) and to pre-charge the complementary bit lines in response to the complement bit line pre-charge signal (BLPCHB).

6. The device of claim 1, wherein:
the local I/O circuit further includes a read bit line (RBL) transistor and a complement read bit line (RBLB) transistor respectively connected to the complementary read bit lines; and
the local I/O circuit is further configured to receive a complement read signal (READB) that activates the read bit line (RBL) transistor and the complement read bit line (RBLB) transistor.

7. The device of claim 1, wherein:
the local I/O circuit further includes:
complementary bit lines;
a bit line (BL) transistor connected to one of the complementary bit lines; and
a complement bit line (BLB) transistor connected to the other of the complementary bit lines; and
the local I/O circuit is further configured to receive a column address of the memory array circuit that activates the bit line (BL) transistor and the complement bit line (BLB) transistor.

8. A device comprising:
a memory array circuit configured to store data therein;
a first circuit configured to receive or transmit the data;
a second circuit configured to transfer the data between the memory array circuit and the first circuit and including:
complementary read bit lines; and
a sense amplifier and read bit line pre-charger circuit connected between the complementary read bit lines and configured to receive a complement sense amplifier pre-charge signal (SAPRB) and to pre-charge the complementary read bit lines in response to the complement sense amplifier pre-charge signal (SAPRB); and
a local control circuit including:
a complement internal sense amplifier pre-charge signal (SAPRBI) generator configured to receive an internal sense amplifier enable signal (SAEI) and a delayed version of the internal sense amplifier enable signal (SAEI) and to generate a complement internal sense amplifier pre-charge signal (SAPRBI); and
a sense amplifier pre-charge signal (SAPR) generator configured to receive the complement internal sense amplifier pre-charge signal (SAPRBI) and to generate a sense amplifier pre-charge signal (SAPR).

9. The device of claim 8, wherein:
the local control circuit further includes a read signal (READ) generator configured to receive the complement internal sense amplifier pre-charge signal (SAPRBI) and the inverted version of the internal complement sense amplifier pre-charge signal (SAPRBI) and to generate a read signal (READ); and
the sense amplifier pre-charge signal (SAPR) generator is configured generate the inverted version of the complement sense amplifier pre-charge signal (SAPRB) in response further to the read signal (READ).

10. The device of claim 8, wherein the sense amplifier and read bit line pre-charger circuit is further configured to receive a sense amplifier enable signal (SAE) and to amplify a voltage difference between the complementary read bit lines in response to the sense amplifier enable signal (SAE).

11. The device of claim 10, wherein the local control circuit is configured to receive an internal clock signal (ICLK) and to generate an inverted version of the sense amplifier enable signal (SAE).

12. The device of claim 8, wherein:
the second circuit further includes complementary bit lines, wherein memory cells of the memory array circuit is connected between the complementary bit lines; and
the second circuit is further configured to receive a complement bit line pre-charge signal (BLPCHB) and to pre-charge complementary bit lines in response to the complement bit line pre-charge signal (BLPCHB).

13. The device of claim 8, wherein:
the second circuit further includes a read bit line (RBL) transistor and a complement read bit line (RBLB) transistor respectively connected to the complementary read bit lines; and
the second circuit is further configured to receive a complement read signal (READB) that activates the read bit line (RBL) transistor and the complement read bit line (RBLB) transistor.

14. The device of claim 8, wherein:
the second circuit further includes:
complementary bit lines;
a bit line (BL) transistor connected to one of the complementary bit lines; and
a complement bit line (BLB) transistor connected to the other of the complementary bit lines; and
the second circuit is further configured to receive a column address of the memory array circuit that activates the bit line (BL) transistor and the complement bit line (BLB) transistor.

15. A method for reading a memory cell, the method comprising:
generating an internal sense amplifier enable signal (SAEI);
generating an internal sense amplifier pre-charge signal (SAPRI) and an inverted version of the internal sense amplifier pre-charge signal (SAPRI) in response to the internal sense amplifier enable signal (SAEI);
receiving the inverted version of the internal sense amplifier pre-charge signal (SAPRI);
generating an inverted version of a complement sense amplifier pre-charge signal (SAPRB) in response to the inverted version of the internal sense amplifier pre-charge signal (SAPRI);
pre-charging complementary read bit lines of the device;
amplifying a voltage difference between the complementary read bit lines; and
providing an output that corresponds to a voltage level on one of the complementary read bit lines.

16. The method of claim 15, further comprising:
generating a read signal (READ) in response to the internal sense amplifier pre-charge signal (SAPRI) and the inverted version of the internal sense amplifier pre-charge signal (SAPRI); and
generating the inverted version of the complement sense amplifier pre-charge signal (SAPRB) in response further to the read signal (READ).

17. The method of claim 15, further comprising generating a sense amplifier enable signal (SAE) based on the internal sense amplifier enable signal (SAEI), wherein amplifying the voltage difference between the complementary read bit lines is in response to the sense amplifier enable signal (SAE).

18. The method of claim 17, further comprising:
receiving an internal clock signal (ICLK); and
generating an inverted version of the sense amplifier enable signal (SAE) in response to the internal clock signal (ICLK).

19. The method of claim 15, further comprising:
receiving a complement bit line pre-charge signal (BLPCHB); and
pre-charging complementary bit lines of the device in response to the complement bit line pre-charge signal (BLPCHB).

20. The method of claim 15, further comprising:
receiving a complement read signal (READB); and
activating a read bit line (RBL) transistor of the device connected to one of the complementary read bit lines in response to the complement read signal (READB).
